(19) United States
(12) Patent Application Publication
(10) Pub. No.: US 2005/0229850 A1
(43) Pub. Date: Oct. 20, 2005

(54) Rotary machine for cvd coatings

(76) Inventors: Stephan Behle, Hahnheim (DE); Andreas Luttringhaus-Henkel, Darmstadt (DE); Gregor Arnold, Bodenheim (DE); Matthias Bicker, Mainz (DE); Jurgen Klein, Mainz (DE)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/514,880

(22) PCT Filed: May 26, 2003
(86) PCT No.: PCT/EP03/05499

§ 371 Date: Jun. 27, 2005

(30) Foreign Application Priority Data
May 24, 2002 (DE) 102 23 288.1
Jun. 1, 2002 (DE) 102 24 395.6
Jun. 7, 2002 (DE) 102 25 607.1
Jun. 11, 2002 (DE) 102 25 985.2
Nov. 16, 2002 (DE) 102 53 512.4
Nov. 16, 2002 (DE) 102 53 513.2

(51) Int. Cl. C23C 16/00

(52) U.S. Cl. 118/719; 427/248.1

(57) ABSTRACT

A method and apparatus are provided for allowing effective and fast CVD coating of workpieces. The invention provides a rotary apparatus for treatment, in particular CVD-coating, which includes a conveyor carousel, treatment stations, which are transported by the conveyor carousel, and at least one first pump device. The first pump device is transported by the conveyor carousel.

The invention relates to a rotary machine and a process for treating workpieces, in particular a rotary machine and a process for CVD coating with rotating pump devices.

The plastic containers which are being used more and more for example for the storage of foodstuffs generally have a relatively high permeability for gases. Consequently, over the course of time carbon dioxide escapes from carbonated drinks which are stored in such containers, and consequently the drinks quickly go flat. Moreover, it is also possible for oxygen to penetrate through the plastic and initiate oxidation processes in foodstuffs stored therein, which likewise significantly shortens their shelf life. On the other hand, plastic containers also have many benefits, such as for example a low weight, a low unit price and stability with respect to mechanical loads on account of the high elasticity compared to glass containers.

To combine these benefits of plastic containers with those of glass containers, including their extremely good barrier effect, it is known to provide plastic containers with barrier coatings, or diffusion barrier layers, which improve the barrier effect of containers of this type by orders of magnitude.

Coatings of this type may even be appropriate on glass containers, for example in the field of pharmaceutical packaging, for example preventing the migration of alkali metal ions out of the glass container wall into the interior by means of a silicon oxide barrier.

One particularly effective and inexpensive technology used to apply layers of this type is chemical vapor deposition (CVD). In the CVD processes, a layer is deposited by means of a reactive chemical gas mixture which surrounds the surface to be coated. In this way, a virtually unrestricted range of possible layers can be produced from mixtures of various gases. Inter alia oxide layers, such as for example the abovementioned SiO₂ layers, have proven suitable diffusion barriers.

A chemically reactive gas mixture for CVD coating can be produced thermally or by ionization of the process gases, for example as a result of the introduction of electromagnetic energy. Since plastics are not generally sufficiently thermally stable or have low softening points, CVD coating under the action of heat is unsuitable for the coating of plastic surfaces. In this case, however, the option of plasma-enhanced CVD (PECVD) coating is recommended. Since in this process too the plasma heats the surface to be coated, plasma impulse CVD (PICVD) coating is also particularly suitable.

To allow a process of this type to be used on an industrial scale, the process times involved require a multiplicity of chambers in which coating is carried out simultaneously or in a time-offset manner. Since PICVD coatings are carried out under low-pressure conditions, this presents the problem of introducing the workpieces to be coated, such as for example the plastic hollow bodies, into the coating regions and evacuating the latter very quickly, since in particular when coating mass-produced items high throughputs through a coating apparatus have to be achieved and therefore there is only a very short time available for the evacuation.

To be able to achieve the required high throughputs, it is advantageous to use a rotary apparatus in which the coating stations for the workpieces which are to be coated rotate along a circular path. With apparatuses of this type, it is possible to realize a continuous coating sequence, in which the individual processing phases are assigned to defined circle segments or angle ranges during the rotation.

An apparatus of this type is known, inter alia, from WO 00 58631. In the case of the conveyor carousel proposed in this document for the plasma treatment of dielectric hollow bodies having a plurality of identical treatment stations each designed to receive at least one hollow body, the treatment stations, in order to be evacuated, are connected to pressure sources by means of distributor devices having rotating, airtight connections. The conveyor carousel has at least two independent and equivalent pressure sources. The treatment stations are divided into groups which are each allocated to one pressure source. Connection to and disconnection from the pressure sources is effected by means of the distributor device with the rotating connections.

However, this conveyor carousel has a number of drawbacks. It has proven expedient, inter alia, for the coating stations not to be evacuated using a single pump apparatus. To reach low pressures quickly, in fact, multistage evacuation at different pumping stages is expedient, whereas the apparatus disclosed by WO 00 58631 provides just one connection of a treatment station to in each case one pressure source.

Furthermore, a rotary connection has to be realized between the pressure sources and the rotating treatment stations. At low pressures, the demands imposed on the leaktightness and the conductance are very high, which entails an increased susceptibility of the apparatus to faults.

Furthermore, a distributor device with rotating, airtight connections requires this device to be arranged on the axis of rotation of the conveyor carousel, whereas the coating stations are arranged at the circumference of the carousel. This requires long vacuum connection lines from the distributor device to the treatment stations. However, this is deleterious to the conductance of the vacuum system and therefore has an adverse effect on the duration of the evacuation time required.

Also, a common connection of two treatment stations belonging to a group to a common pressure source can lead to crosstalk between the treatment stations, which are connected to one another via the pressure source, if these stations are at different pressure levels.

Therefore, the invention is based on the object of providing a rotary machine and a process for CVD coating which allows particularly effective and fast coating of workpieces.

This object is achieved, in a very surprisingly simple way, by a rotary apparatus or plasma module for treating, in particular for CVD or plasma coating, workpieces as claimed in claim 1, and a process as claimed in claim 22. Advantageous refinements to the apparatus are given in the subclaims. Accordingly, a rotary apparatus according to the invention comprises
a conveyor carousel or plasma wheel,
treatment or plasma stations which are transported by the conveyor carousel, and
at least one first pump device or feed device for an operating medium. The first pump device is transported by the conveyor carousel.

On account of the fact that the pump device is transported by the conveyor carousel, there is no need for a vacuum-tight rotary feed when connecting this pump device to the treatment stations. Also, the proximity to the pump device, which cannot otherwise be realized when using a rotary feed, allows the feed lines to the treatment stations to be kept short and provided with large cross sections.

By contrast, with rotating connections, the difficulties of keeping the connection sealed increase with the diameter and therefore with the conductance which can be achieved.

The process according to the invention for the CVD coating of workpieces in a rotary apparatus, in particular as described above, accordingly provides that
at least one workpiece is introduced into a treatment station on a rotating conveyor carousel,
the treatment station is connected to at least one first pump device,
the treatment station is evacuated, and
the workpiece is coated,
   wherein the first pump device is conveyed with the conveyor carousel.

After coating has taken place, it is then possible for the treatment stations to be vented and the workpieces removed.

The connection of the one or more pump devices to the treatment stations can advantageously be produced by means of a distributor device. This distributor device may advantageously comprise a distributor, in particular in the form of a ring distributor, to which the pump devices and connection lines to the coating chambers are connected.

The connection of a specific treatment station to a pump device may in this case be effected by the distributor device as a function of the angular position of the treatment station on the conveyor carousel. For this purpose, the distributor device may comprise control valves. Therefore, the treatment stations can be connected to the first or second pump device as a result of switching of the control valves, with the valves being opened or closed at corresponding angular positions and thereby producing the connection to the pump device or the distributor.

It is particularly preferable for the rotary apparatus according to the invention also to have at least one second pump device or external feed device arranged in a fixed position. The treatment stations may in this case also be connected to this second pump device in order to be evacuated. For this purpose, the second, fixed pump device, like the first, co-rotating pump device, may be connected to at least one, in particular also the same, distributor device for connecting the treatment stations to the second pump device.

The evacuation of the treatment stations is preferably carried out in at least two steps or evacuation phases, preferably with switching between different pump devices between the steps. To allow the final pressure to be reached quickly, it is advantageous, for example, if the first and second pump devices are adapted for different pressure ranges. These may then be connected to the treatment stations in succession in order of decreasing pressure ranges during the evacuation, for example, so that each pump device operates in the pressure range which is optimum for it. In this context, it is advantageous in particular if the co-rotating first pump device is optimized for a lower pressure range than the second pump device, since as the pressure drops the suction power decreases for the same suction capacity. Accordingly, for short evacuation times, in particular at low pressures, good conductances of the feed lines are important in order to obtain a suction capacity which is as efficient as possible.

Moreover, however, it is also possible, in addition to switching between pump devices, to realize additional connection of pump devices in order to match the suction power to the pressure prevailing in the coating chamber. It is particularly advantageous for the evacuation, both in the case of single-stage pump evacuation and in the case of evacuation in a plurality of steps, to be performed in such a way that a pump device is connected to in each case just one treatment station. This is advantageous since it prevents a pump device from being connected to two treatment stations whose coating chambers have different pressures. Otherwise, this would lead to a mean pressure being established in the two treatment stations as a result of gas flowing via the pump device, and therefore to an increase in pressure in the chamber which was initially at the lower pressure.

In particular in the case of rotary apparatuses with a high throughput, it may also be advantageous to provide more than just a single pump device for an evacuation step or evacuation phase. Therefore, according to a further embodiment of the invention, the pump power can be increased by the rotary apparatus comprising at least two identical or equivalent pump devices. These identical or equivalent pump devices may be co-rotating first and/or fixed second pump devices. Then, according to this embodiment of the invention, the evacuation of the treatment stations is carried out using the identical or equivalent pump devices during at least one evacuation phase.

According to an advantageous refinement of this embodiment of the invention, in each case one of the identical or equivalent pump devices is connected to at least one treatment station for the duration of the at least one evacuation phase. For this purpose, there is a distributor device for connecting the treatment stations to the pump devices, this distributor device in each case connecting one of the identical or equivalent pump devices to at least one treatment station for the duration of the evacuation phase.

In this case, by way of example, a treatment station or a group of treatment stations is connected to a first of the identical pump devices on entering a circle segment assigned to an evacuation phase. The next treatment station or group of treatment stations is then connected to the second of the identical pump devices on entering the circle segment. This sequence of connection to the pump devices may then advantageously be continued cyclically.

The co-rotating arrangement of the first pump device in the rotary apparatus according to the invention makes it possible to realize short connection lines in the pump device or pump devices to the coating stations, with large line cross sections. In this way, it is possible for the effective suction capacity of the first pump device to be reduced only relatively moderately compared to the actual maximum suction capacity of the pump device. The following relationship applies between the actual suction capacity S and the effective suction capacity Seff reduced by the feed line:

$$\frac{1}{{S}_{eff}} = \frac{1}{S} + \frac{1}{L} , \qquad ( 1 )$$

where L denotes the conductance or flow conductance of the feed line.

The flow conductance is determined to a significant extent by the cross section of the pipelines and by way of example for a line is given by the following relationship:

$$L = \frac{{q}_{pV}}{{p}_{0} - {p}_{2}} \qquad ( 2 )$$

In the above, p₀ denotes the pressure upstream of the line and p₂ denotes the pressure at the pump-side end of the line. q_{pV} denotes the p·V flow through the vacuum line. By way of example, for the case of laminar flow, this is given by (cf. for example “Handbuch Vakuumtechnik”, [Vacuum technology handbook], 6th Edition, Vieweg-Verlag 1997):

$${q}_{pV} = \frac{π}{128 η} \cdot \frac{d}{l} \cdot \frac{{p}_{0}}{} \qquad ( 3 )$$

η denotes the dynamic viscosity of the gas. The variables d and 1 denote the diameter and length of the line. It can be seen from equation 3 that the conductance of the vacuum lines is highly dependent on their length and in particular their diameter. Furthermore, it can also be seen from equation (2) in conjunction with equation (3) that the conductance decreases as the pressure differences drop. Accordingly, as the pressures drop, the pressure differences which occur also become smaller. Therefore, the line cross section or the coefficient of diameter to length, d/l, is less critical for the conductance at higher pressures than at lower pressure ranges. The arrangement according to the invention of the first pump device on the conveyor carousel, with the resultant possibility of realizing particularly short vacuum lines from this pump device to the treatment stations, therefore allows evacuation to be significantly accelerated. According to one embodiment of the invention, therefore, by way of example the quotient d/l of diameter d of the vacuum line between first pump device and a distributor device to its length l can be greater than or equal to 1/15, preferably greater than or equal to 1/10.

In an embodiment of the invention with at least one second, fixed pump device, the latter can be used as a preliminary stage to the first, co-rotating pump device and/or as a first pump stage in the evacuation of a treatment station. In both cases, the second, fixed pump device then works in a higher pressure range than the first, co-rotating pump device. Accordingly, as per equations (2) and (3), the conductance increases for a given line cross section, so that the vacuum connection from the fixed, second pump device to the rotating conveyor carousel and the length of the vacuum lines is less critical here. According to one embodiment of the apparatus according to the invention, by way of example, the second pump device may be arranged in such a way, and a vacuum line from the pump device to a distributor device, such as in particular a ring distributor, or to a first pump device can be dimensioned in such a way that the quotient d/l of diameter d of the vacuum line between second pump device and a distributor device to its length l is greater than or equal to 1/60, preferably greater than or equal to 1/30.

According to one embodiment of the method according to the invention, the treatment stations are evacuated in four evacuation steps. Suitable steps are achieved if the pump devices are connected in such a way that the pressure in a treatment station is reduced in steps, in a first step down to ≦200 mbar, in a subsequent second step down to ≦80 mbar, in a subsequent third step down to ≦1.5 mbar, and in a subsequent fourth step down to ≦0.1 mbar.

Furthermore, a further embodiment of the invention provides for evacuation in five steps. In this case, by way of example, the evacuation can be carried out as in the four-step method described above, then in a subsequent fifth step the pressure in the treatment station is reduced to ≦0.01 mbar. In both embodiments, by way of example, in a further step it is possible to switch over to a pump device for extracting the process gas.

Roots pumps, inter alia, have proven suitable vacuum sources for the pump device. These pumps are distinguished by a high suction capacity at low pressures, in particular in the fine-vacuum range.

As an alternative or in addition, the second pump device may also be operated as a preliminary stage of the first pump device or be connected to the latter. As a result, a preliminary vacuum is provided for the first pump device, with the result that the suction capacity of the latter increases at low pressures. The second pump device may, for example, comprise one or more slide-vane rotary pumps. This type of pump is characterized by high suction powers at relatively high pressures in the low-vacuum range.

The fixed second pump device may, for example, be connected to the conveyor carousel by means of a rotary feed or rotary coupling. If the second pump device is intended for a relatively high pressure range, the demands imposed with regard to conductance and leak rate of the rotary feed are considerably lower than if a connection of this type were to have to produce the final pressure. According to one embodiment, in this case the leak rate of the rotary feed is 10⁻¹ mbar l/sec or below, preferably in the range between 10⁻² and 10⁻⁴ mbar l/sec in stationary and/or rotating operation.

It has proven expedient if the evacuation using the first and/or second pump devices is in each case also carried out in a plurality of stages at different pressure ranges. Compared to single-stage evacuation, it is in this case possible to significantly reduce the overall pump power and therefore the size of the pumps used. Accordingly, it is advantageously possible to provide at least two fixed first and/or second pump devices which are successively connected to the treatment stations when the conveyor carousel rotates.

In order, furthermore, to be able to provide a high suction power at low pressures in the coating chamber, it is also advantageous if a first pump device comprises at least two pump stages connected in series. It is also possible for two or more first pump devices to be connected in series from time to time during the evacuation phase, for example by suitable switching of the control valves.

It is particularly preferable for the rotary apparatus according to the invention to be used for PECVD or PICVD coating, with the workpiece being coated as a result of process gas and electromagnetic energy being fed into the treatment station. Moreover, for this purpose the apparatus has a device for feeding process gas into the treatment stations and a device for supplying electromagnetic energy, preferably microwaves. Then, a plasma is generated in the process gas atmosphere by means of the microwaves, the reaction products of which plasma are deposited on the surface of the workpieces to be coated. In particular, it is in this case also possible to carry out internal coating of workpieces which are in the form of hollow bodies, such as for example ampoules or bottles made from plastic or glass, by a plasma being ignited inside the workpieces. For this purpose, process gas is introduced into the interior region of the workpieces.

If only the inner sides of workpieces of this type are to be coated, the workpieces can be held in corresponding mounts in the treatment stations, which then seal off the interior region from the environment. In this way, it is then possible for the process gas to be introduced only into the inner region. If a suitable pressure is set, a plasma is then ignited only in the interior region.

The process gas can also be sucked out by a first pump device during coating. If new process gas is supplied at the same time, the process gas atmosphere is continuously regenerated during the coating operation. In this case, undesirable reaction products produced in the plasma are continuously discharged, with the result that particularly pure and high-quality coatings can be produced.

The invention is described in more detail below on the basis of exemplary embodiments and with reference to the appended drawings, in which identical reference symbols denote identical or similar parts.

In the drawings:

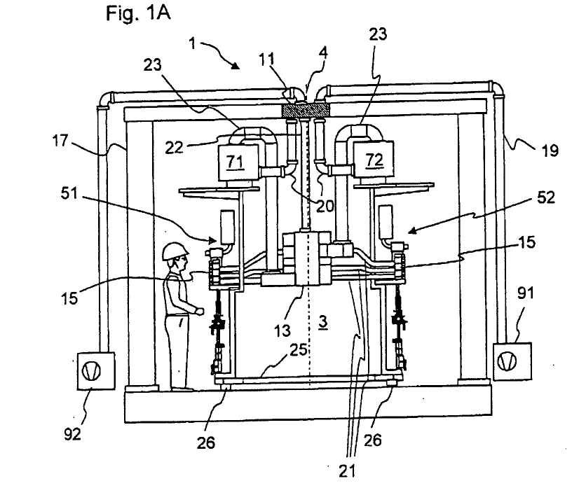

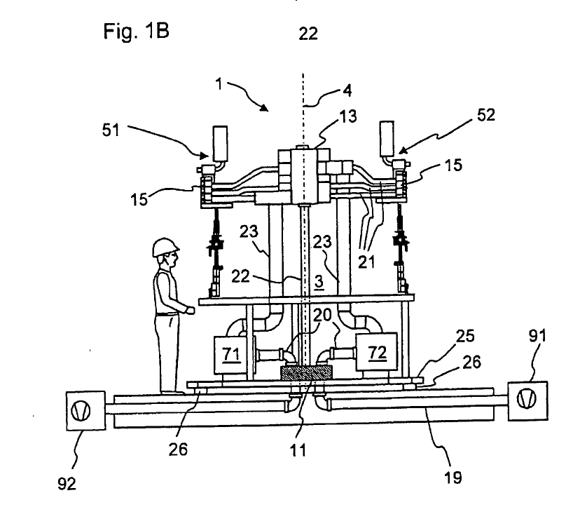

FIG. 1A shows a view of an embodiment of the rotary apparatus according to the invention,

FIG. 1B shows a view of a further embodiment of the rotary apparatus according to the invention,

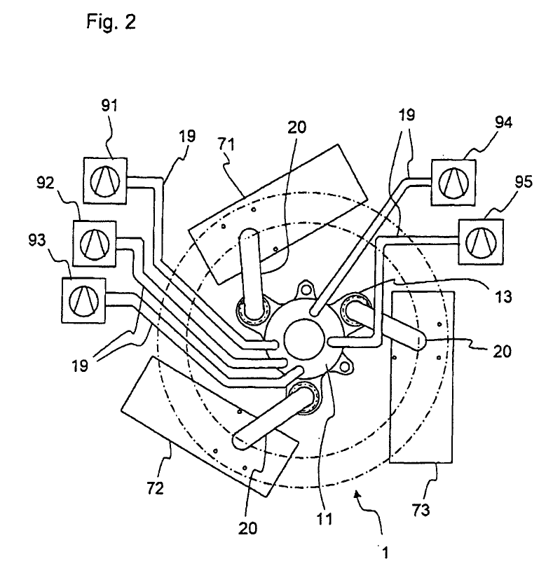

FIG. 2 shows a diagrammatic plan view of parts of a rotary apparatus according to the invention,

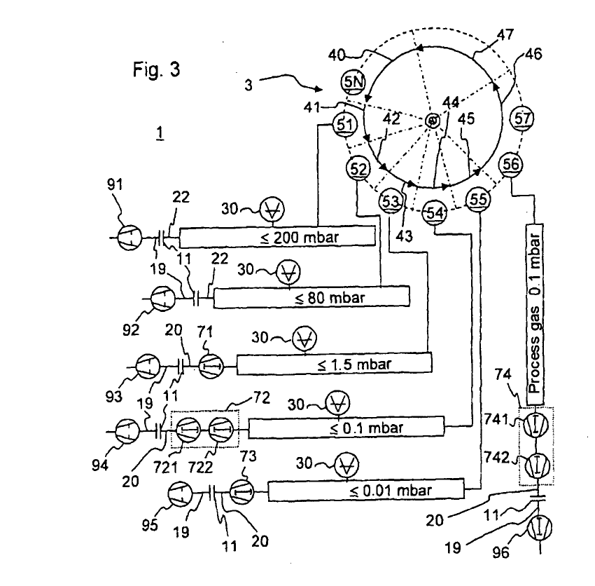

FIG. 3 shows a vacuum circuit diagram for one embodiment of a multi-stage vacuum circuit of a rotary apparatus according to the invention, and

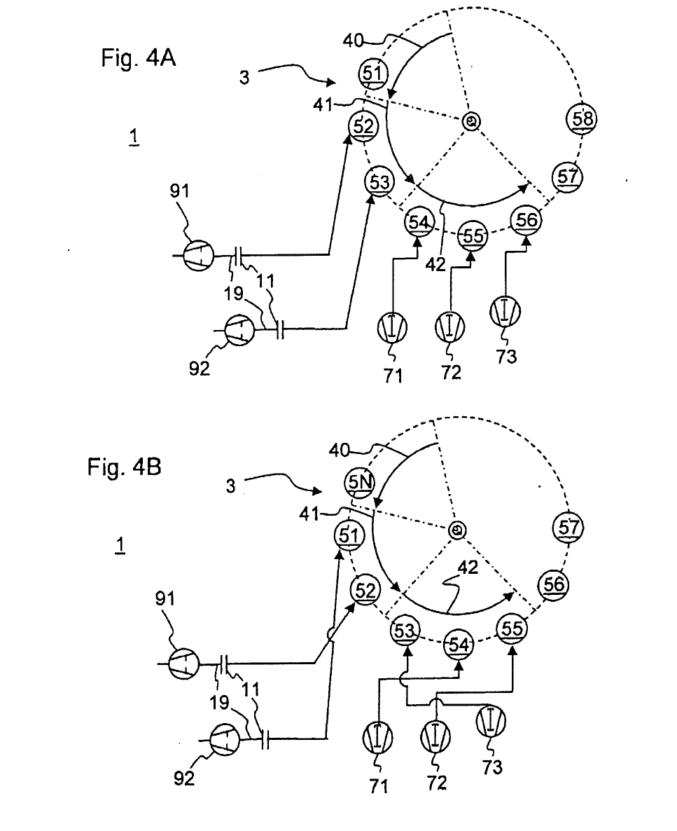

FIGS. 4A and 4B show a further embodiment of a vacuum circuit diagram having a plurality of equivalent pump devices.

FIG. 1A shows a diagrammatic view of a rotary apparatus according to the invention, which is denoted overall by 1.

The rotary apparatus 1 has a conveyor carousel 3 on which are mounted a plurality of treatment stations, of which two treatment stations 51 and 52 are illustrated in the drawing. The conveyor carousel 3 is mounted rotatably in a carrying frame 17. For this purpose, the conveyor carousel 3 is installed on a carrier plate 25, which for its part is mounted on rotary bearings 26 and can therefore rotate within the carrier frame 17 about the axis of rotation 4.

Also mounted on the conveyor carousel 3 are co-rotating first pump devices, of which two first pump devices 71 and 72 are shown in the drawing.

In addition, the apparatus according to the invention also has second, fixed pump devices, which are connected to a rotary feed 11 via vacuum lines or connection pipes 19. FIG. 1A illustrates two pump devices 91, 92 by way of example. However, the apparatus may also have further second pump devices. Further vacuum lines 20 of the conveyor carousel 3, which are connected to the gas outlets of the first pump devices 71 and 22, branch off from the rotary feed 11. The fixed, second pump devices 91, 92, . . . therefore act as a preliminary stage for the first, co-rotating pump devices 71 and 72. On account of the fact that these pump devices are operated as a preliminary stage under a low vacuum, the demands imposed on the rotary feed 11 with regard to leak rate and conductance are also low. This reduces both the manufacturing costs of an apparatus of this type and, given a suitable design, the susceptibility of the rotary feed to faults. A leak rate of the rotary feed of the order of magnitude of 10⁻¹ mbar l/sec or below, preferably in the range between 10⁻² and 10⁻⁴ mbar l/sec in stationary and/or rotating operation, can still be tolerated according to an embodiment of the invention.

On account of the fact that the second, fixed pump devices work in higher pressure ranges compared to the first, co-rotating pump devices, the conductance of the vacuum lines 19, for a given diameter, for example in accordance with equations (2) and (3) for laminar flow, is higher than for pressure ranges at which the first, co-rotating pump devices are used. Accordingly, the greater lengths of the vacuum lines 19 caused by the fixed arrangement and the rotary feed 13 located in the vacuum connection for these pump devices 91, 92 do not have as much of an influence on their pumping capacity as would be the case if the first pump devices were to be arranged in a fixed position.

The first pump devices 71 and 72 are connected to a ring distributor 13 via vacuum lines or coupling lines 23 with a large cross section. Distributor lines or connection lines 21, which are connected to control lines 15, branch off from the ring distributor 13. For their part, the control valves 15 are coupled to the coating chambers 51, 52. The ring distributor 13 and the control valves are accordingly parts of a distributor device which produces the connection between the pump devices and the treatment stations.

When the conveyor carousel 2 is rotating, defined angle ranges, which the respective treatment station 51, 52 passes through, are assigned to the individual processing phases involved in the coating, such as for example introduction, evacuation, coating and removal. The connection of a treatment station 51, 52 to a first pump device 71, 72 and also the disconnection from the latter are effected by switching of the control valves 15.

The individual co-rotating first pump devices 71 and 72 may in particular also operate at different pressure stages. In this case, the evacuation of the treatment stations can be carried out in a plurality of stages, with the evacuation at each stage being switched from a pump at a higher pressure stage to a pump at a lower pressure stage. Accordingly, the pump devices 71 and 72 are successively connected to the treatment stations as the conveyor carousel rotates. The switching between the pump devices 71 and 72 is preferably also effected by the control valves 15. The control valves 15 can be actuated, for example, by mechanical control cams which the control valves 15 mounted on the conveyor carousel are moved past. However, it is also possible for the valves to be of electromechanical design, in which case the switching of these valves is then effected by switching currents being switched on and off.

In the case of multistage evacuation, the second, fixed pump devices can be used not only as a preliminary stage for the co-rotating, first pump devices 71, 72, but rather it is also possible, in particular in the initial phase of evacuation, for the treatment station to be connected to at least one fixed, second pump device. This is expedient, for example, in order for the treatment station to be evacuated from atmospheric pressure to a low vacuum. For this purpose, in the embodiment shown in FIG. 1A, there is a vacuum line 22 which connects the ring distributor 13, via the rotary feed 11, to the fixed, second pump device 92. Then, the coating chambers 51, 52 can be connected from the ring distributor 13, by means of the control valves 15, to the pump device 92 in a first stage of the evacuation in order to achieve a low vacuum.

FIG. 1B shows a further embodiment of an apparatus according to the invention. In this embodiment, the rotary feed 11 is arranged beneath the ring distributor 13. In this way, it is possible for the pump devices 91 and 92 to be arranged in the vicinity of the floor and to be connected to the rotary feed 11 using vacuum lines which are particularly short in relation to their diameter. This also allows very high conductances to be achieved by the vacuum connection from the first pump devices 71, 72, which rotate with the conveyor carousel 3, and the ring distributor 13 to the fixed, second pump devices 91, 92. This vacuum connection comprises the vacuum lines 19 from the pump devices 91, 92 to the rotary feed 11 and the vacuum lines 20 and 22 leading from the rotary feed to the pump devices 71, 72 and/or the ring distributor 13.

With the apparatus according to the invention as illustrated by way of example in FIGS. 1A and 1B, it is possible to reach conductances at which the effective suction capacity of the pump devices, which in each case pump via the vacuum connection, is only slightly reduced compared to the actual maximum suction capacity of the pump devices. The arrangement according to the invention with co-rotating first pump devices achieves this in particular also for the vacuum connection to the treatment stations 51, 52, since the pump devices can be arranged correspondingly close to the treatment stations and the vacuum lines can be kept short. For example, the dimensions of the vacuum lines 23 between first pump device 71, 72 and ring distributor 13 can be so short that the quotient of diameter d of the vacuum line 23 to its length l is greater than or equal to 1/15, or even greater than or equal to 1/10. If, in the embodiments illustrated with reference to FIG. 1A or 1B, the pump devices were to be mounted in a fixed position rather than rotating with the conveyor carousel and were to be connected to the treatment stations via a rotary feed, significantly longer vacuum lines would be required. For design reasons, given the same diameter the quotient d/l of diameter d and line length l would be only 1/60 or below. By way of example, for a line diameter of 10 centimeters, line lengths of approximately 6 meters would be required, whereas the co-rotating arrangement allows this length to be reduced to approximately 1 to 1.5 meters or even less. In addition, in this way it is also possible to reduce deviations in the lines, as may be required, for example, with long vacuum connections. Each deviation through 90°, for example with regard to the conductance for a line with a diameter of 10 centimeters, corresponds to an additional lengthening of the line by approximately 0.3 meter.

FIG. 2 shows a diagrammatic plan view of parts of a rotary apparatus 1. This embodiment of the rotary apparatus has three co-rotating first pump devices 71, 72, 73, which are connected to the ring distributor 13. It is preferable for Roots pumps, which are characterized by a high suction capacity at low pressures, to be used for the first pump devices. On the other hand, pumps of this type have only a low compression capacity, and consequently preliminary stages are generally required to reach low final pressures after evacuation has concluded. As has already been explained above, these preliminary stages are provided by second, fixed pump devices, which are connected to the pump devices 71, 72 and 73 via a rotary feed 11.

In detail, the embodiment of the rotary apparatus 1 illustrated in FIG. 2 has a total of five fixed pump devices 91 to 95 of this type. The pump devices 91 to 95 do not all have to be of the same type. Rather, they may differ in terms of their suction power and the optimum pressure range. It is preferable for slide-vane rotary pumps, which have high suction powers in the low-vacuum range, to be used for the pump devices 91 to 95.

FIG. 3 shows a vacuum circuit diagram for an embodiment of a multistage vacuum circuit of a rotary apparatus according to the invention. In this embodiment of the invention, the evacuation is carried out in four or five steps. Moreover, the process gas is pumped out during the coating phase following the evacuation. The total of six individual evacuation phases together with the pumping-out of the process gas are assigned angle regions or sectors 41 to 46 through which the individual treatment stations 51, 52, . . . , 5N move on the conveyor carousel 3 as a result of the rotation of the carousel. In each of the sectors 41 to 46, in each case one treatment station is connected to an individual pump device or to multistage pump devices. Throughout the entire evacuation process, including the pumping-out of process gas, each of the pump devices is connected to in each case just one treatment station. When an angle range assigned to a specific evacuation phase is left, or before the following angle range is entered, the connection of the treatment station to a pump device is then disconnected again. The connection and disconnection can likewise be effected by means of a distributor device which comprises control valves and a ring distributor. The pressures can be measured and checked using suitable pressure gage tubes 30, for example Pirani measurement tubes.

After the workpieces have been supplied in a loading region, which is assigned to a sector 40, the treatment station, as it passes through the sector 41, is connected to a fixed, second pump device 91, which evacuates the coating region of the coating station down to a pressure of ≦200 mbar. When a treatment station is in the following sector 42, it is connected to a further, fixed pump device 92, which is optimized for a lower pressure range. As it passes through this sector, the pump device 92 evacuates the coating region of the treatment station to a pressure of ≦80 mbar. Then, co-rotating first pump devices 71, 72 and, in the case of evacuation in five stages, also an optional further first pump device 73 are used to reach even lower pressures during further evacuation phases, so that short feed lines with a large cross section can be used and difficulties with sealing the rotary feed can be avoided. In this case, the treatment stations are evacuated to less than or equal to 1.5 mbar, less than or equal to 0.1 mbar and, in the case of evacuation in five steps, less than or equal to 0.01 mbar as they pass through the angle ranges 53, 54 and 55, so that the pressure in each of the evacuation phases is reduced by approximately one order of magnitude.

To achieve a high machine capacity or a high throughput, the time between the loading of two treatment stations is very short. The evacuation times can be kept correspondingly short. The finely graded evacuation process is highly advantageous in this context, since the pumps required for this purpose can be kept relatively small.

Moreover, second, fixed pump devices 93, 94 and 95 are connected upstream of the first pump devices 71, 72 and 73, as a preliminary stage, so that pumping is effected in two stages, in order to reduce or avoid high compression ratios across individual pumps.

The fixed, second pump devices 91 to 94 are each designed as slide-vane rotary pumps which are eminently suitable for pumping against atmospheric pressure. By contrast, all the co-rotating first pump devices 71 to 74 comprise Roots pumps in order to provide high suction powers at low pressures.

The pump devices 72 and 74 are additionally of two-stage design and each comprise Roots pumps 721, 722 and 741, 742, respectively.

Following transit through the sectors 41 to 45, evacuation to the final pressure is concluded and the coating chamber then passes through an angle range 46 assigned to coating. Here, process gas is admitted to the coating region and microwaves are supplied, with the result that a plasma is ignited and the workpiece within the treatment station is coated. During this processing phase, the coating installation is connected to the pump device 74, which is of two-stage design and, like the other first pump devices, is connected to a second, fixed pump device. To eliminate the large quantities of gas produced, the preliminary stage or fixed, second pump device 96 in this case also comprises a Roots pump.

After coating has finished, the treatment station passes into a removal region assigned to the sector 47, where the coated workpiece is removed and conveyed away by means of a suitable conveyor device. Like the loading of the treatment stations, the removal can also be effected by allocation wheels (not shown in FIG. 3).

FIGS. 4A and 4B show a vacuum circuit diagram for a further embodiment of the invention at two different instants; these figures, for the sake of simplicity, only illustrate the vacuum circuit diagram for the evacuation of the coating stations. In the embodiment of the invention illustrated on the basis of this vacuum circuit diagram, a plurality of equivalent pump devices are used for individual evacuation phases, in order to further increase the pump power. The co-rotating first pump devices 71, 72 and 73 are designed to be equivalent to one another in this embodiment. The fixed, second pump devices 91 and 92 are also equivalent and accordingly operate at the same pressure and with the same pump power.

According to this embodiment of the invention, the evacuation of the treatment stations 51, 52, . . . , 5N is carried out during a first evacuation phase, assigned to sector 41, using the equivalent pump devices 91, 92 and during a second evacuation phase, assigned to sector 42, using the equivalent co-rotating first pump devices 71, 72, 73.

Specifically, in each case one of the equivalent pump devices 91, 92 or 71, 72, 73 is connected to at least one treatment station for the duration of the respective evacuation phase assigned to the sectors 41 or 42.

The treatment stations 51, 52, . . . , 5N are in this case connected to a distributor device which, as explained with reference to FIGS. 1A and 1B, may comprise a ring distributor 13 and valves 15.

On entering one of the sectors 41, 42, the treatment stations are each connected to one of the equivalent pump devices 91, 92 or 71-73 for the duration of the respective evacuation phase, i.e. for the time it takes to pass through the sectors or circle segments 41 or 42.

In the position of the conveyor carousel 3 shown in FIG. 4A, the treatment station 52 is connected to the pump device 91, the treatment station 53 is connected to the pump device 92, the treatment station 54 is connected to the pump device 71, the treatment station 55 is connected to the pump device 72 and the treatment station 56 is connected to the pump device 73.

In the position shown in FIG. 4B, the conveyor carousel 3 has rotated onward, so that the treatment station 51 has entered angle region 41. At the same time, the treatment station 53 has finished the evacuation phase associated with angle region 41 and has entered the subsequent sector 42 assigned to a further evacuation phase, where the treatment station 53 has been connected to the co-rotating pump device 73. When the evacuation phase associated with sector 51 ended, the pump device 92 connected to this treatment station 53 was disconnected from this station and then connected with the treatment station 51 which had newly entered the sector 41.

The connection and disconnection of the pump devices 71-73 are carried out in a similar way during passage through the sector 42 or at the start and end of the evacuation phase associated with this sector, with the pump devices 91 and 92 or 71, 72 and 73 being connected cyclically or continued cyclically for the duration of the respective evacuation phase.

As an alternative to the embodiment of the invention illustrated with reference to FIGS. 4A and 4B, instead of individual treatment stations it is also possible for in each case groups of at least two treatment stations to be connected to in each case one pump device, and these treatment stations are then in each case evacuated in groups.

### LIST OF REFERENCE SYMBOLS

1 Rotary apparatus
3 Conveyor carousel
4 Axis of rotation
51, 52, Treatment stations
. . . , 5N
71-74 First, co-rotating pump devices
721, 722, Roots pumps
741, 742
91-96 Second, fixed pump devices
11 Rotary feed
13 Ring distributor
15 Control valves
17 Carrier frame
19-23 Vacuum lines
25 Carrier plate
26 Bearing
30 Pressure gage tube
40-47 Angle ranges

1. A rotary apparatus for treating workpieces, comprising:
a conveyor carousel;
a plurality of treatment stations, wherein the plurality of treatment stations are transported by the conveyor carousel (3); and
at least one first pump device, wherein the at least one first pump device is transported by the conveyor carousel.

2. The rotary apparatus of claim 1, further comprising at least one distributor device for connecting the plurality of treatment stations to the at least one first pump device.

3. The rotary apparatus of claim 2, wherein the at least one distributor device comprises a ring distributor.

4. The rotary apparatus of claim 2, wherein the at least one distributor device comprises control valves.

5. The rotary apparatus of claim 1, wherein the at least one first pump device comprises at least one Roots pump.

6. The rotary apparatus of claim 1, further comprising a distributor device and a vacuum line having a length and a diameter, wherein the diameter of the vacuum line between the at least one first pump device and the distributor device to the length of the vacuum line have a quotient that is greater than or equal to 1/15.

7. The rotary apparatus of claim 1, further comprising at least one second pump device arranged in a fixed position.

8. The rotary apparatus of claim 7, wherein the at least one first pump device and the at least one second pump device are adapted for different pressure ranges.

9. The rotary apparatus of claim 7, wherein the at least one second pump device is connected as a preliminary stage to the at least one first pump device.

10. The rotary apparatus of claim 7, wherein the at least one second pump device comprises at least one slide-vane rotary pump.

11. The rotary apparatus of claim 7, wherein the at least one second pump device is connected to the conveyor carousel by rotary feed.

12. The rotary apparatus of claims 11, wherein the rotary feed has a leak rate of 10⁻¹ millibar per second or below in a stationary and/or a rotary operation.

13. The rotary apparatus of claim 7, wherein the at least one second pump device is connected to at least one distributor device for connecting the plurality of treatment stations to the at least one second pump device.

14. The rotary apparatus of claim 7, wherein the at least one second pump device is at least two second pump devices, the at least two second pump devices being successively connected to the plurality of treatment stations when the plurality of treatment stations are transported by the conveyor carousel.

15. The rotary apparatus of claim 1, wherein the at least one first pump device is at least two first pump devices, the at least two first pump devices being successively connected to the plurality of treatment stations when the plurality of treatment stations are transported by the conveyor carousel.

16. The rotary apparatus of claim 1, wherein the at least one first pump device discharges a process gas.

17. The rotary apparatus of claim 1, wherein the at least one first pump device comprises at least two pump stages connected in series.

18. The rotary apparatus of claim 1, wherein the at least one first pump device is two equivalent pump devices.

19. The rotary apparatus of claim 18, further comprising a distributor device for connecting the plurality of treatment stations to the two equivalent pump devices, wherein the distributor device connects one of the two equivalent pump devices to at least one of the plurality of treatment stations for the duration of an evacuation phase.

20. The rotary apparatus of claim 1, further comprising a device for feeding process gas into the plurality of treatment stations.

21. The rotary apparatus of claim 1, further comprising a device for supplying electromagnetic energy.

22. A process for the CVD coating of at least one workpiece in a rotary apparatus, comprising:
introducing at least one workpiece into a treatment station on a rotating conveyor carousel;
connecting the treatment station to at least one first pump device, wherein the at least one first pump device is conveyed with the conveyor carousel;
evacuating the treatment station; and
coating the at least one workpiece.

23. The process of claim 22, wherein the coating step comprises feeding process gas and electromagnetic energy into the treatment station.

24. The process of claim 22, wherein the process further comprises the steps of venting the treatment station, and removing the at least one workpiece from the treatment station.

25. The process of claim 22, wherein the process further comprises connecting the treatment station to at least one fixed second pump device.

26. The process of claim 25, wherein the at least one first pump device and the at least one fixed second pump device are successively connected to the treatment stations.

27. The process of claim 26, wherein the at least one fixed second pump device is operated as a preliminary stage to the at least one first pump device.

28. The process of claim 22, wherein the at least one first pump device is a plurality of first pumping devices, and wherein the step of coating further comprises sucking out a process gas by one of the plurality of first pump devices.

29. The process of claim 22, wherein the at least one first pump device is at least two first pumping devices, and wherein the evacuating step further comprises connecting the at least two first pumping devices in series.

30. The process of claim 25, wherein the evacuating step further comprises switching a plurality of control valves to disconnect the treatment station from the at least one first pump device and to connect the treatment station to the at least one fixed second pump device.

31. The process of claim 25, wherein the step of evacuating comprises at least two evacuation steps.

32. The process of claim 31, wherein the at least one first pump device is a first pump device and a second pump device, wherein the at least one fixed second pump device is a first fixed second pump device and a second fixed second pump device, wherein the first pump device and the first fixed second pump device comprise a first group of pump devices, wherein the second first pump device and the second fixed second pump device comprise a second group of pump devices, and wherein the evacuation step further comprises switching between the first group of pump devices to the second group of pump devices between the at least two evacuation steps.

33. The process of claim 32, wherein the at least two evacuation steps comprise four evacuation steps.

34. The process of claim 33, wherein the four evacuation steps comprise decreasing a pressure in the treatment station in a first step to less than or equal to 200 millibar in a second step decreasing the pressure to less than or equal to 80 millibar in a third step, decreasing the pressure to less than or equal to 1.5 millibar, in a fourth step decreasing the pressure to less than or equal to 0.1 millibar.

35. The process of claim 22, wherein the evacuating step further comprises connecting a pump device to one treatment station.

36. The process of claim 22, wherein the evacuating step further comprises evacuating the treatment station using at least two equivalent pump devices.

37. The process as claimed in claim 31, wherein the evacuating step further comprises evacuating the treatment station using at least two equivalent pump devices, and wherein the at least two equivalent pump devices are connected to the treatment station for the duration of at least one evacuation step of the at least two evacuation steps.

38. The process of claim 22, wherein the at least one workpiece is in the form of a hollow body having an inner region, and wherein the coating step comprises igniting a plasma in the inner region.
